(19) United States
(12) Patent Application Publication
(10) Pub. No.: US 2025/0038475 A1
(43) Pub. Date: Jan. 30, 2025

(54) MULTIBEAM SEMICONDUCTOR LASER ELEMENT

(71) Applicant: Ushio Denki Kabushiki Kaisha, Tokyo (JP)

(72) Inventors: Yutaka INOUE, Tokyo (JP); Shigeta SAKAI, Tokyo (JP); Susumu SORIMACHI, Tokyo (JP)

(73) Assignee: Ushio Denki Kabushiki Kaisha, Tokyo (JP)

(21) Appl. No.: 18/781,427

(22) Filed: Jul. 23, 2024

(30) Foreign Application Priority Data
Jul. 27, 2023 (JP) 2023-122824

(51) Int. Cl. H01S 5/042; H01S 5/02335; H01S 5/0234; H01S 5/40

(52) U.S. Cl. CPC H01S 5/04256; H01S 5/02335; H01S 5/0234; H01S 5/04254; H01S 5/4031

(57) ABSTRACT

A semiconductor laser element includes a plurality of three or more laser resonators integrated adjacent to each other in the first direction. Each laser resonator has an independent power supply electrode, a second direction which is regarded as a longitudinal direction, and an end face which is coated. A plurality of electrode pads are formed in a pad region adjacent to the laser region in the first direction. Each of the wirings for connection extends in the first direction and is electrically connected the power supply electrode of the corresponding laser resonator and the corresponding electrode pad. The thick film pad is formed on the pad region and is higher than the multilayered wiring structure of the wirings for connection.

### BACKGROUND

### 1. Technical Field

The present disclosure relates to a multibeam semiconductor laser element.

### 2. Description of the Related Art

In an electronic device such as a printer or a head mounted display (HMD), a semiconductor laser is used as a light source. In order to cope with high resolution of such electronic device that handles images, a multibeam semiconductor laser element is adopted.

In order to downsize the lens and the MEMS mirror, a narrower beam pitch is required. In a case where the beam pitch is narrower than the ball diameter of wire bonding or the solder pattern width of die bonding, it is not possible to secure the area for wire bonding or die bonding directly to the electrode on the upper surface of the laser resonator, and as a result, it is necessary to form the electrode pad close to the end of the chip (semiconductor substrate). In this case, the connection wiring (multilayered wiring) connecting the electrode pad and the laser resonator straddles the laser resonator (JP 2010-135731 A).

The present inventors have studied a multibeam semiconductor laser element having a narrow beam pitch, and has recognized the following problems.

End faces of a plurality of laser resonators of the multibeam semiconductor laser element are subjected to anti-reflection (AR) coating or high reflection (HR) coating. FIG. 1 is a diagram illustrating a coating step. Prior to the coating step, the semiconductor chip 4 (die) is cut out from the wafer as a die lay (LD bar) 6 in which a plurality of semiconductor chips 4 are integrated. The LD bar 6 is sandwiched and supported and fixed by the spacers 2 which are jigs. In this state, the cleave plane 8 of the LD bar 6 is coated. After the coating, a plurality of semiconductor chips 4 are cut out from the LD bar 6 by a pelletizing step.

In a multibeam semiconductor laser element having a narrow beam pitch, an electrode pad is disposed at a chip end. Wiring (referred to as connection wiring) connecting the power supply electrode (P-side electrode) formed on the upper surface of the central laser resonator and the electrode pad crosses the adjacent laser resonator. Focusing on the intersection of the connection wiring and the laser resonator, an insulating layer is inserted between the connection wiring and the power supply electrode of the laser electrode to form a multilayered wiring structure. This multilayered wiring structure has a height (distance from the chip surface) higher than other portions. Therefore, in the coating step, when the LD bar 6 is fixed by the spacers 2, the multilayered wiring structure comes into contact with the spacers 2, and the pressure concentrates. As a result, the reliability of the semiconductor laser element may be deteriorated. For example, when the insulating layer of the multilayered wiring structure is cracked, an electrical short circuit occurs between adjacent emitters.

It should be noted that this problem should not be regarded as a general recognition for those skilled in the art, and further, this problem has been uniquely recognized by the present inventors.

### SUMMARY

One aspect of the present disclosure is made in view of such problems, and one of the exemplary purposes of the present disclosure is to provide a semiconductor laser element in which a decrease in reliability in a coating step is suppressed.

One aspect of the present disclosure relates to a multibeam semiconductor laser element. The multibeam semiconductor laser element includes a plurality of three or more laser resonators integrated adjacent to each other in a first direction in a laser region of a single semiconductor substrate. Each laser resonator has an independent power supply electrode, a second direction which is regarded as a longitudinal direction, and an end face which is coated. A plurality of electrode pads corresponding to a plurality of laser resonators is formed in a pad region adjacent to the laser region in the first direction. The power supply electrode of the corresponding laser resonator and the corresponding electrode pad are electrically connected by a plurality of wirings for connection. The wirings for connection have a multilayered wiring structure at a position intersecting the laser resonator. The multibeam semiconductor laser element further includes a thick film pad formed in the pad region and having a height higher than the multilayered wiring structure of the wirings for connection.

Note that any combination of the above components and mutual replacement of the components and expressions of the present disclosure among methods, apparatuses, systems, and the like are also effective as aspects of the present disclosure.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a diagram illustrating a coating step;

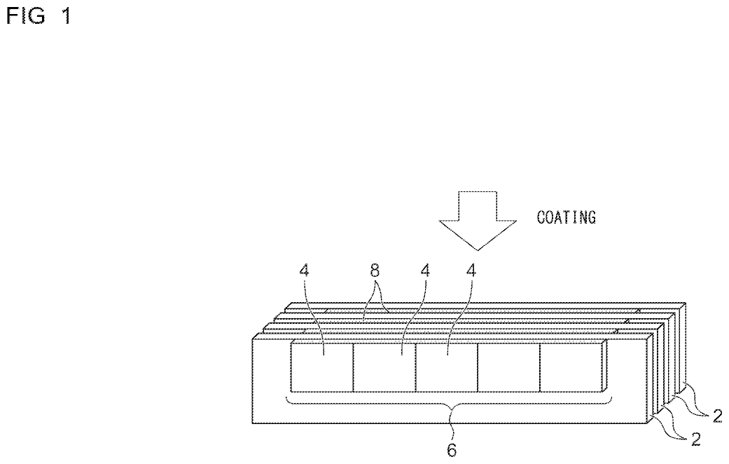

FIG. 2 is a perspective view of the semiconductor laser element according to a first embodiment;

FIG. 3 is a cross-sectional view of the semiconductor laser element in FIG. 2;

FIG. 4 is a view for describing a coating step for the semiconductor laser element in FIG. 2;

FIG. 5 is a cross-sectional view of a laser device including the semiconductor laser element;

FIG. 6 is a cross-sectional view of a laser device including the semiconductor laser element;

FIG. 7 is a cross-sectional view of a laser device including the semiconductor laser element;

FIG. 8 is a perspective view of a semiconductor laser element according to a second embodiment;

FIG. 9 is a perspective view of a semiconductor laser element according to a third embodiment;

FIG. 10 is a perspective view of a semiconductor laser element according to a fourth embodiment;

FIG. 11 is a perspective view of a semiconductor laser element according to a fifth embodiment;

FIG. 12 is a perspective view of a semiconductor laser element according to a sixth embodiment;

FIG. 13 is a perspective view of a semiconductor laser element according to a seventh embodiment;

FIG. 14 is a perspective view of a semiconductor laser element according to a modification;

FIG. 15 is a perspective view of a semiconductor laser element according to an eighth embodiment;

FIG. 16 is a plan view of a semiconductor laser element according to a ninth embodiment;

FIG. 17 is a plan view of a semiconductor laser element according to a tenth embodiment;

FIG. 18 is a plan view of a semiconductor laser element according to an eleventh embodiment;

FIG. 19 is a plan view of a semiconductor laser element according to a twelfth embodiment;

FIG. 20 is a perspective view of a semiconductor laser element according to a thirteenth embodiment;

FIG. 21 is a plan view illustrating an example of the semiconductor laser element in FIG. 20;

FIG. 22 is a cross-sectional view of the semiconductor laser element in FIG. 21;

FIG. 23 is a perspective view of a semiconductor laser element according to a fourteenth embodiment; and

FIG. 24 is a diagram for describing a method for manufacturing the semiconductor laser element.

### DETAILED DESCRIPTION

### Outline of Embodiment

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later.

A multibeam semiconductor laser element according to one embodiment includes: a plurality of three or more laser resonators (laser waveguides) integrated adjacent to each other in a first direction in a laser region of a single semiconductor substrate, each laser resonator having an independent power supply electrode, a second direction being a longitudinal direction, and end faces being coated; a plurality of electrode pads corresponding to the plurality of laser resonators and formed in a pad region adjacent to the laser region in the first direction; and a plurality of wirings for connection corresponding to the plurality of laser resonators, each of the wirings for connection extending in the first direction, and electrically connecting the electrode pad corresponded to the power supply electrode of the laser resonator corresponded, the wirings for connection having a multilayered wiring structure at a position intersecting the laser resonator; and a thick film pad formed in the pad region and having a height higher than a height of the multilayered wiring structure of the wirings for connection.

According to this configuration, in the coating step, when the LD bar including a plurality of semiconductor laser elements is sandwiched and fixed by spacers, pressure concentrates on the thick film pad. As a result, the force applied to the multilayered wiring structure can be reduced, and the reliability of the semiconductor laser element can be enhanced.

In one embodiment, the thick film pad may be formed of the same material as the electrode pad.

In one embodiment, the height of the electrode pad may be higher than the height of the multilayered wiring structure of the wirings for connection, and the electrode pad may be a thick film pad. In this case, in the coating step, a surface of the thick film pad (electrode pad) comes into contact with the spacer, so that the material of the coating does not adhere to the surface of the electrode pad. Therefore, in the subsequent assembly step, the degree of adhesion of the bonding wire and the soldering can be increased.

In one embodiment, the thick film pad may be provided separately from a plurality of electrode pads.

In one embodiment, the power supply electrode may be a stripe-shaped electrode, an interlayer insulating film may be formed on the stripe-shaped electrode, and the wirings for connection may be formed on the interlayer insulating film.

In one embodiment, the interlayer insulating film may be polyimide. Polyimide can fill the irregularities of the base and tends to have a flat surface, and therefore the effect of flattening the wirings for connection and improving the film coverage can be achieved.

In one embodiment, the thick film pad may be formed of the same material as the interlayer insulating film.

In one embodiment, the multibeam semiconductor laser element may further include a blocking wall that is formed across a plurality of laser resonators and at least over the entire laser region and has substantially the same height as the thick film pad. According to this structure, when one end face of the laser resonator is being coated, the coating material can be prevented from adhering to the opposite end face, and deterioration in performance of the coating film can be suppressed.

In one embodiment, the power supply electrode may be a stripe-shaped electrode. An interlayer insulating film may be formed on the stripe-shaped electrode, and a blocking wall may be formed of the same material as the interlayer insulating film.

In one embodiment, a plurality of thick film pads are formed, and the heights of the plurality of thick film pads may be substantially equal. As a result, in the coating step, the spacer can be supported in parallel with the semiconductor substrate, and a large number of LD bars and spacers can be stably laminated. Substantially equal means equal to the degree to which this effect can be obtained.

In one embodiment, the spacing of a plurality of laser resonators may be less than or equal to 100 μm.

A semiconductor laser device according to one embodiment includes the multibeam semiconductor laser element according to any one of the above and a support substrate. The multibeam semiconductor laser element is mounted on the support substrate in a junction-up manner.

A semiconductor laser device according to one embodiment includes the multibeam semiconductor laser element according to any one of the above and a support substrate. The multibeam semiconductor laser element is mounted on the support substrate in a junction-down manner, and a plurality of electrode pads and a plurality of pads on the support substrate are connected by solder.

In one embodiment, the support substrate may include a plurality of substrate-side electrode pads corresponding to a plurality of laser resonators. Each substrate-side electrode pad may be formed in such a manner of overlapping the wirings for connection and the electrode pad of the corresponding laser resonator. The wirings for connection and the electrode pad of each laser resonator may be bonded to the corresponding substrate-side electrode pad by solder. According to this configuration, heat dissipation can be enhanced.

A method for manufacturing the multibeam semiconductor laser element according to one embodiment may include a plating step of forming the wirings for connection and the thick film pad by plating. The power supply in the plating step may be performed via the stripe-shaped electrode and the intersection between the stripe-shaped electrode and the connection wiring, or may be performed via an opening in a case where the opening is provided in the interlayer insulating film.

### EMBODIMENTS

Hereinafter, the present disclosure will be described based on preferred embodiments with reference to the drawings. Identical or like constituting elements, members, processes shown in the drawings are represented by identical symbols, and a duplicate description will be omitted as appropriate. In addition, the exemplary embodiments are not intended to limit the disclosure, but are merely examples, and all features described in the exemplary embodiments and combinations thereof are not necessarily essential to the disclosure.

Dimensions (thickness, length, width, and the like) of each member described in the drawings may be appropriately enlarged or reduced for easy understanding. Furthermore, the dimensions of the plurality of members do not necessarily indicate the magnitude relationship therebetween, and when a certain member A is drawn thicker than another member B in the drawing, the member A may be thinner than the member B.

### First Embodiment

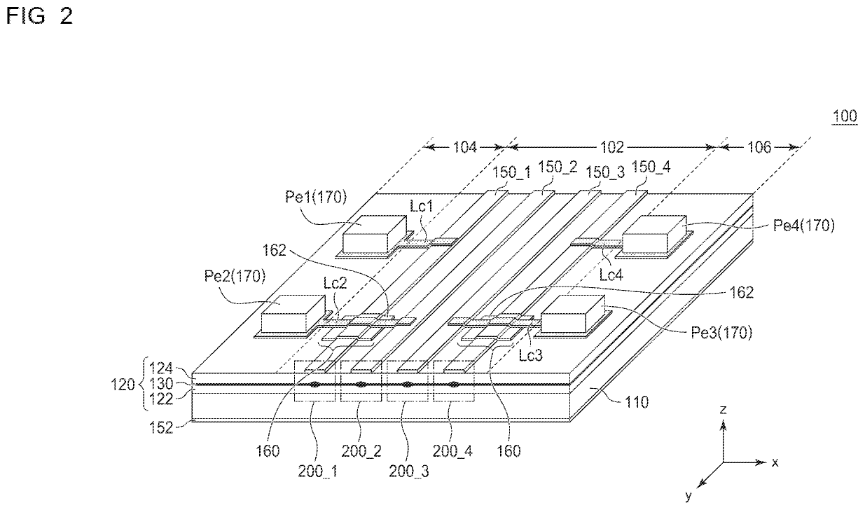

FIG. 2 is a perspective view of a semiconductor laser element 100 according to a first embodiment. The semiconductor laser element 100 is an end face emission type semiconductor laser element, and is a multibeam semiconductor laser having a plurality of m (m≥3) emitters. In the present embodiment, the number of emitters is four.

The semiconductor laser element 100 includes an N-type semiconductor substrate 110 and a laminated growth layer 120 formed on the N-type semiconductor substrate 110. The laminated growth layer 120 includes an N-type cladding layer 122, a light emitting layer 130, a P-type cladding layer 124, and a P-type contact layer (not illustrated), and is sequentially laminated on the N-type semiconductor substrate 110. The light emitting layer 130 includes an N-type guide layer (lower guide layer), an active layer including a quantum well layer, and a P-type guide layer (upper guide layer). The materials of the N-type semiconductor substrate 110 and the laminated growth layer 120 may be selected according to a necessary oscillation wavelength, and are not particularly limited in the present disclosure.

The semiconductor laser element 100 has a laser region 102 in the center and pad regions 104 and 106. In the laser region 102, m (m≥3) laser resonators 200 adjacent in the first direction (x direction) are formed. Each laser resonator 200 has a stripe structure extending in a second direction (y direction) orthogonal to the first direction (x direction).

A waveguide structure for confining light is formed in the laminated growth layer 120, and cleavage planes at both ends of the waveguide structure serve as mirrors to form a Fabry-Perot type laser resonator 200. In this example, four laser resonators 200_1 to 200_4 are formed, and a beam is emitted in the y direction from the emission end face. The end face of each laser resonator is coated to provide a desired reflectance.

The waveguide structure can be, for example, an embedded ridge waveguide.

Alternatively, the waveguide structure may be a CSP (Channeled Substrate Planer) structure in which a groove is formed in the N-type semiconductor substrate 110 along the waveguide, and the thickness of the N-type cladding layer 122 at the groove portion is relatively thick.

The embedded ridge structure or the CPS structure is a waveguide structure using a refractive index distribution, and the present disclosure is not limited thereto, and a gain waveguide structure using a gain distribution may be used. These structures are optical confinement structures and can also be grasped as current confinement structures.

A power supply electrode (P-side electrode) 150 is formed on the upper surface of the laser resonator 200. In order to enable the laser resonator 200 to be driven independently, the power supply electrodes 150 are electrically insulated from each other, and the P-type semiconductor has electric resistance between the emitters and can be driven electrically independently. In the present embodiment, the power supply electrode 150 is a stripe-shaped electrode extending along the y direction on the upper surface of the laser resonator 200.

In order to supply power to the laser resonator 200, a plurality of chip side electrode pads (hereinafter, simply referred to as an electrode pad) Pe1 to Pe4 and a plurality of wirings for connection Lc1 to Lc4 are provided corresponding to the plurality of laser resonators 200_1 to 200_4.

The plurality of electrode pads Pe1 to Pe4 are formed on the pad regions 104 and 106 adjacent to the laser region 102 in the x direction. Bonding wires are connected to the electrode pads Pe1 to Pe4 in a case of junction-up mounting, and solders are connected to the electrode pads Pe1 to Pe4 in a case of junction-down mounting.

Each of the wirings for connection Li (i=1, 2, 3, and 4) electrically connects the power supply electrode 150 of the corresponding laser resonator 200_i to the corresponding electrode pad Pi.

For the two inner laser resonators (200_2 and 200_3) of the plurality of laser resonators 200_1 to 200_4, the wirings for connection Lc2 and Lc3 cross the outer laser resonators. Specifically, the wirings for connection Lc2 crosses the laser resonator 200_1. The wirings for connection Lc2 have a multilayered wiring structure 160 at a position intersecting the laser resonator 200_1. The multilayered wiring structure 160 includes an interlayer insulating film 162 formed between the connection wiring Lc2 and the power supply electrode 150.

Similarly, the wirings for connection Lc3 crosses the laser resonator 200_4. The wirings for connection Lc4 have a multilayered wiring structure 160 at a position intersecting the laser resonator 200_4.

As a material of the interlayer insulating film 162, an inorganic material such as SiO₂ or an organic material such as polyimide can be used. SiO₂ is advantageous in terms of heat dissipation since SiO₂ is likely to be made into thin films. Polyimide can fill irregularities of the base and tends to have a flat surface, and therefore there is an advantage that the wirings for connection Lc can be flattened and the film coverage is improved, but it is difficult to form a thin film, making it difficult to be cleaved or pelletized.

In the present embodiment, the semiconductor laser element 100 includes a thick film pad 170. The thick film pad 170 is formed on the pad regions 104 and 106, and is higher than the multilayered wiring structure 160 of the wirings for connection Lc2 and Lc3. The height can be grasped as a distance from a reference surface orthogonal to the z axis, and for example, the front surface or the back surface of the N-type semiconductor substrate 110 can be regarded as the reference surface. Preferably, the difference Δh between the height of the thick film pad 170 and the height of the multilayered wiring structure 160 is preferably larger than 1 μm, and more preferably 5 μm or more.

In the present embodiment, the thick film pad 170 also serves as the electrode pads Pe1 to Pe4, and is made of a metal material. In other words, the electrode pads Pe1 to Pe4 are formed to be thicker than a normal electrode pad so as to function as the thick film pad 170.

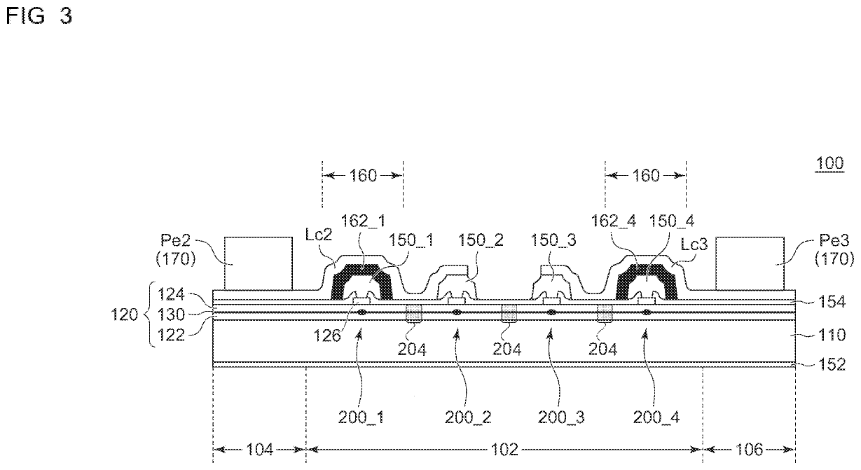

FIG. 3 is a cross-sectional view of the semiconductor laser element 100 in FIG. 2. This cross-sectional view illustrates a cross section of the semiconductor laser element 100 in the xz plane at a position where the connection wirings Lc2 and Lc3 are formed. A high electric resistance region 204 is formed between adjacent laser resonators 200 by, for example, ion implantation. A contact insulating film 154 is formed on the laminated growth layer 120, and the contact insulating film 154 is opened on the lower surface of the power supply electrode. The contact insulating film 154 is made of a material such as SiO₂.

A P-type contact layer 126 is formed on the P-type cladding layer 124, and a power supply electrode 150 is formed on the P-type contact layer 126. An interlayer insulating film 162_1 is formed on the power supply electrode 150_1 of the laser resonator 200_1. The connection wiring Lc2 is formed across the interlayer insulating film 162_1. An interlayer insulating film 162_4 is formed on the power supply electrode 150_4 of the laser resonator 200_4. The connection wiring Lc3 is formed across the interlayer insulating film 162_4.

The above is the configuration of the semiconductor laser element 100. Next, advantages thereof will be described.

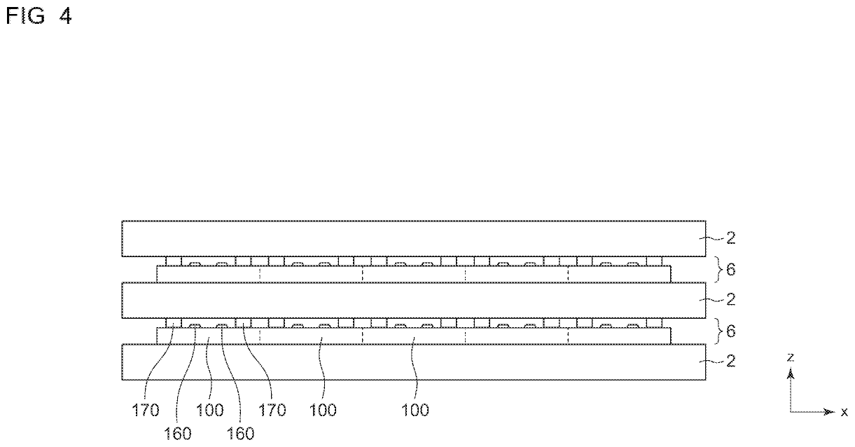

FIG. 4 is a view for describing a coating step for the semiconductor laser element 100 in FIG. 2. An LD bar 6 including a plurality of semiconductor laser elements 100 is cut out from the wafer. The LD bar 6 is sandwiched and supported and fixed by the spacers 2. In this state, the end face of each semiconductor laser element 100 is subjected to coating processing.

The semiconductor laser element 100 is in contact with the spacer 2 at the thick film pad 170, which has the highest height, and the multilayered wiring structure 160 is not in contact with the spacer 2. Therefore, the pressure applied to the multilayered wiring structure 160 can be reduced, and the decrease in the reliability of the semiconductor laser element 100 can be prevented.

Next, an example of mounting of the semiconductor laser element 100 will be described.

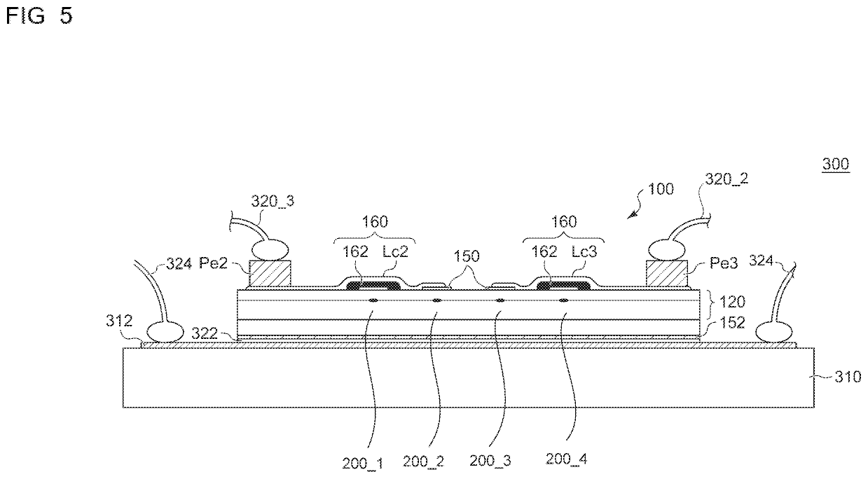

FIG. 5 is a cross-sectional view of a semiconductor laser device 300 including a semiconductor laser element 100. The semiconductor laser device 300 includes a support substrate (also referred to as a submount) 310 and the semiconductor laser element 100. The semiconductor laser element 100 is mounted on the support substrate 310 in a junction-up manner, that is, in a direction in which an N-side electrode 152 is on the support substrate 310 side.

The electrode pads Pe2 and Pe3 are connected to a lead (anode) of a package (not illustrated) or an anode of a drive circuit via bonding wires 320_2 and 320_3. The N-side electrode 152 is connected to the electrode 312 formed on the support substrate 310 via a solder 322. The electrode 312 is connected to a lead (cathode) of a package (not illustrated) or a cathode of a drive circuit via a bonding wire 324.

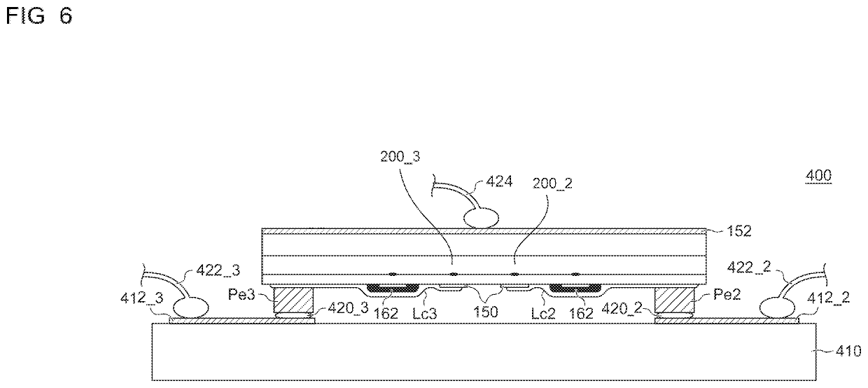

FIG. 6 is a cross-sectional view of a laser device including the semiconductor laser element 100. The laser device 400 includes a support substrate 410 and the semiconductor laser element 100. The semiconductor laser element 100 is mounted on the support substrate 410 in a junction-down manner, that is, in a direction in which the power supply electrode 150 is on the support substrate 410 side.

A plurality of substrate-side electrode pads 412_1 to 412_4 corresponding to the plurality of laser resonators 200_1 to 200_4 are formed on the support substrate 410. In the cross-sectional view of FIG. 6, only two substrate-side electrode pads 412_2 to 412_3 are shown. The electrode pads Pe2 and Pe3 are connected to substrate-side electrode pads (hereinafter, simply referred to as an electrode pad) 412_2 and 412_3 formed on the support substrate 410 via solders 420_2 and 420_3. Each of the electrode pads 412_2 and 412_3 is connected to a lead (anode) of a package (not illustrated) or an anode of a drive circuit via bonding wires 422_2 and 422_3. The N-side electrode 152 is connected to a lead (cathode) of a package (not illustrated) or a cathode of a drive circuit via a bonding wire 424.

As illustrated in FIG. 6, the electrode pads Pe3 and Pe4, which are thick film pads, also play a role of preventing the multilayered wiring structure 160 and the support substrate 410 from coming into contact with each other at the time of junction-down mounting.

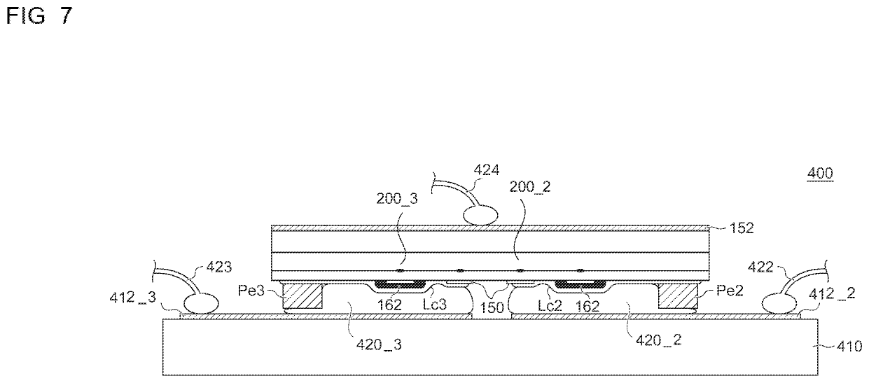

FIG. 7 is a cross-sectional view of a laser device including the semiconductor laser element 100. FIG. 7 is a mounting example of junction down similarly to FIG. 6. In FIG. 7, the substrate-side electrode pad 412_2 corresponding to each laser resonator 200_2 is formed in such a manner of overlapping the electrode pad Pe2 and the connection wiring Lc2 of the corresponding laser resonator. Then, the connection wiring Lc2 and the electrode pad Pe2 are connected to the substrate-side electrode pad 412_2 via the solder 420_2. The same applies to the connection wiring Lc3 side.

According to the configuration of FIG. 7, heat dissipation can be enhanced as compared with the configuration of FIG. 6.

### Second Embodiment

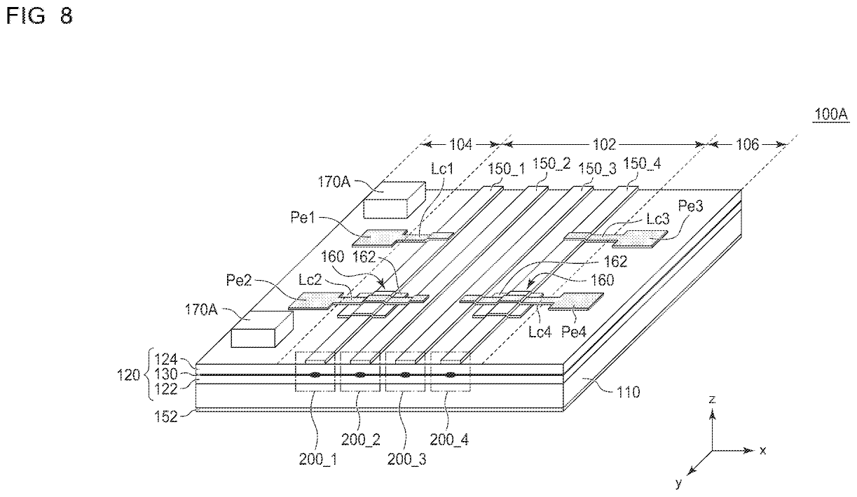

FIG. 8 is a perspective view of a semiconductor laser element 100A according to a second embodiment. In the first embodiment, the electrode pads Pe1 to Pe4 also serve as the thick film pads 170. On the other hand, in FIG. 8, the thick film pad 170A is formed independently of the electrode pads Pe1 to Pe4. In this configuration, the thick film pad 170A may be made of a metal or an insulator. In a case where the thick film pad 170A is formed of an insulator, the thick film pad 170A can be formed using the same material as the interlayer insulating film 162 and under the same film forming process.

The thick film pad 170A functions to prevent the multilayered wiring structure 160 from coming into contact with the spacer during the coating step, and this function may be exhibited in the state of the LD bar. As illustrated in FIG. 8, in a case where the thick film pad 170A is formed only on the pad region 104 on one side, this function is exhibited together with the thick film pad 170A similarly formed on another adjacent chip.

Naturally, an additional thick film pad 170A may be formed.

### Third Embodiment

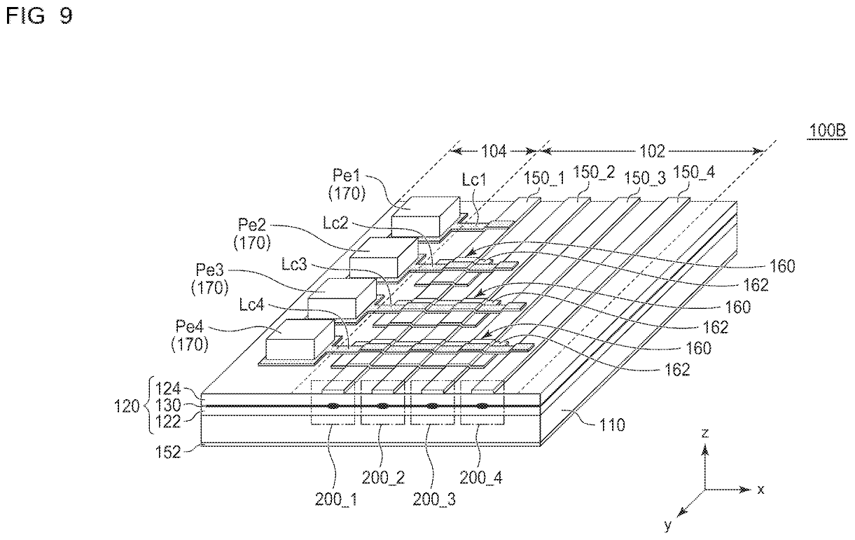

FIG. 9 is a perspective view of a semiconductor laser element 100B according to a third embodiment. In the semiconductor laser element 100B, the pad region 104 is provided only on one side of the chip, and the laser region 102 is provided close to the opposite side. All of the four electrode pads Pe1 to Pe4 are formed on the pad region 104.

The connection wiring Lc2 has a multilayered wiring structure 160 at an intersection with power supply electrode 150_1. The connection wiring Lc3 has a multilayered wiring structure 160 at an intersection with power supply electrodes 150_2 and 150_3. The connection wiring Lc4 has a multilayered wiring structure 160 at an intersection with the power supply electrode 150_2, 150_3, and 150_4.

### Fourth Embodiment

The semiconductor laser element 100A in FIG. 8 and the semiconductor laser element 100B in FIG. 9 have a cantilever structure in a case of junction-down mounting, and thus are structurally unstable when the lateral width of the chip is wide. In a fourth embodiment, a structure suitable for junction-down mounting will be described.

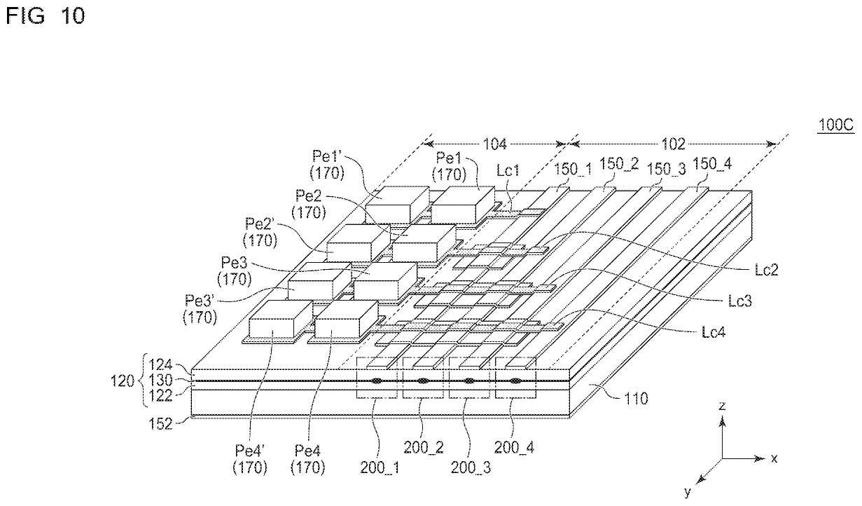

FIG. 10 is a perspective view of a semiconductor laser element 100C according to the fourth embodiment. The semiconductor laser element 100C is obtained by further adding electrode pads Pe1′ to Pe4′, which are thick film pads 170, to the semiconductor laser element 100B in FIG. 9. The electrode pad Pei′ (i=1, 2, 3, and 4) is adjacent to and electrically connected to the electrode pad Pei in the x direction.

According to this configuration, in a case of junction mounting, the semiconductor laser element 100 can be supported by the electrode pad Pe′ in addition to the electrode pad Pe, so that structural strength can be increased.

### Fifth Embodiment

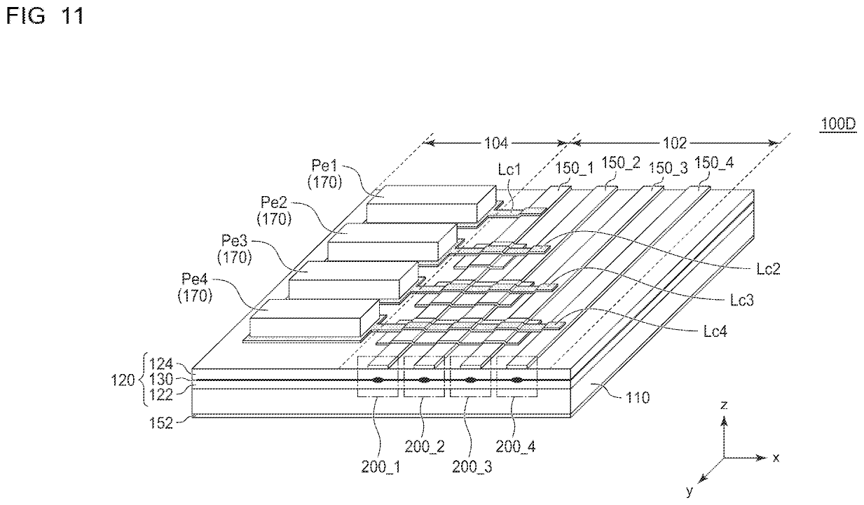

FIG. 11 is a perspective view of a semiconductor laser element 100D according to a fifth embodiment. The lateral width (width in the x direction) of the electrode pad Pe is wider than that of the electrode pad Pe in FIG. 9. It can also be grasped that the electrode pads Pe and Pe′ in FIG. 10 are continuously and integrally formed. According to this configuration, in a case of junction mounting, the semiconductor laser element 100 can be supported by the wide electrode pad Pe, so that structural strength can be increased.

### Sixth Embodiment

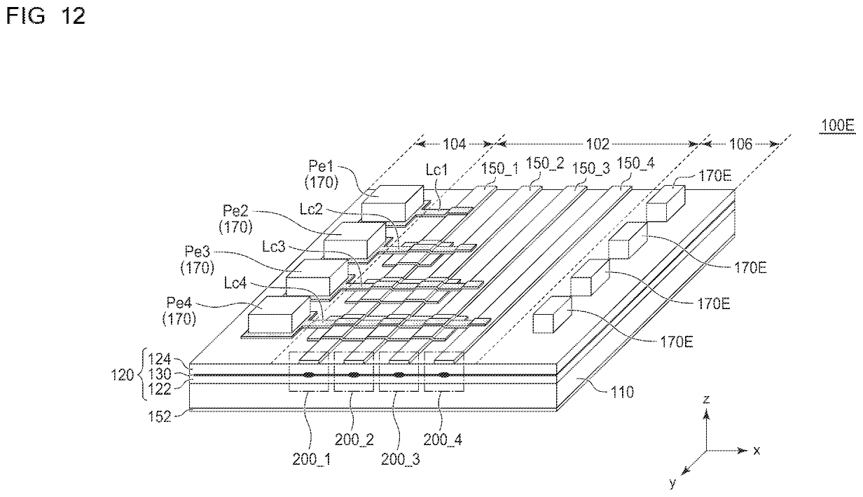

FIG. 12 is a perspective view of a semiconductor laser element 100E according to a sixth embodiment. A semiconductor laser element 100E is obtained by adding a plurality of thick film pads 170E to the semiconductor laser element 100B in FIG. 9. The plurality of thick film pads 170E are formed on the pad region 106. The thick film pad 170E is an electrode pad, and is soldered to the support substrate when junction-down mounting is performed. Here, since the thick film pad 170E does not contribute to driving of the semiconductor laser element 100, it is not necessary to be electrically connected to the laser resonators 200_1 to 200_4.

According to this structure, when junction-down mounting is performed, a cantilever structure is not formed, so that structural strength can be increased.

### Seventh Embodiment

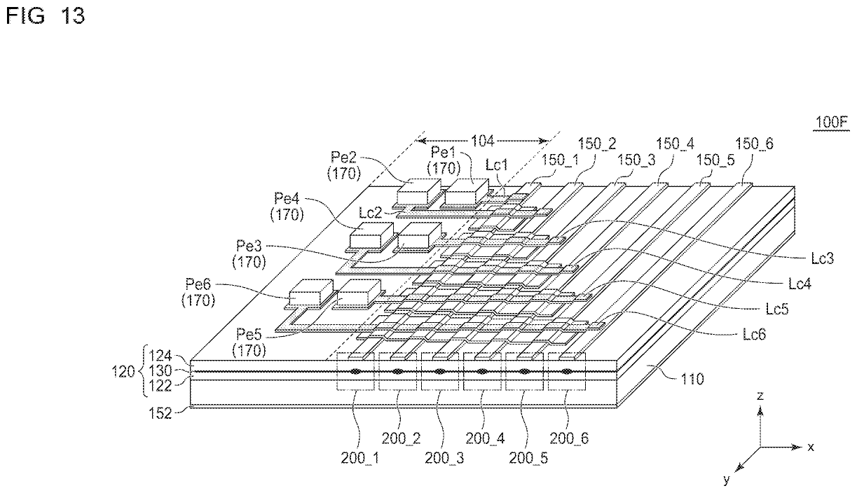

FIG. 13 is a perspective view of a semiconductor laser element 100F according to a seventh embodiment. The semiconductor laser element 100F has six beams (six emitters), and includes six laser resonators 200_1 to 200_6 and six electrode pads Pe1 to Pe6. The electrode pads Pe1 to Pe6 are thick film pads 170 and are arranged in two rows. According to this configuration, similarly to the semiconductor laser element 100C in FIG. 10, in the case of junction-down mounting, the cantilever is supported by the two rows of electrode pads Pe, so that structural strength can be increased. The configuration of FIG. 13 is effective in a case where the resonator length, that is, the length of the chip in the y direction is short.

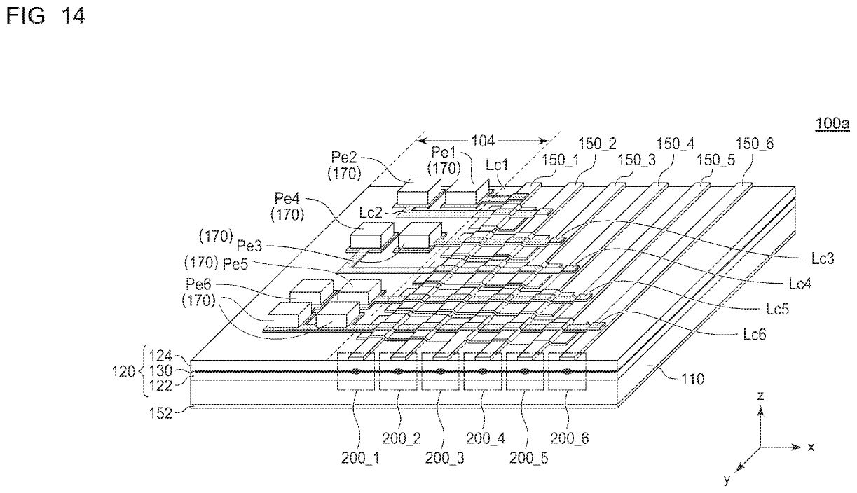

FIG. 14 is a perspective view of a semiconductor laser element 100a according to a modification. Three or more electrode pads Pe may be provided for one connection wiring Lc. In this example, three electrode pads Pe6 are provided for the connection wiring Lc6. The plurality of electrode pads Pe6 may be arranged in the x direction or in the y direction.

### Eighth Embodiment

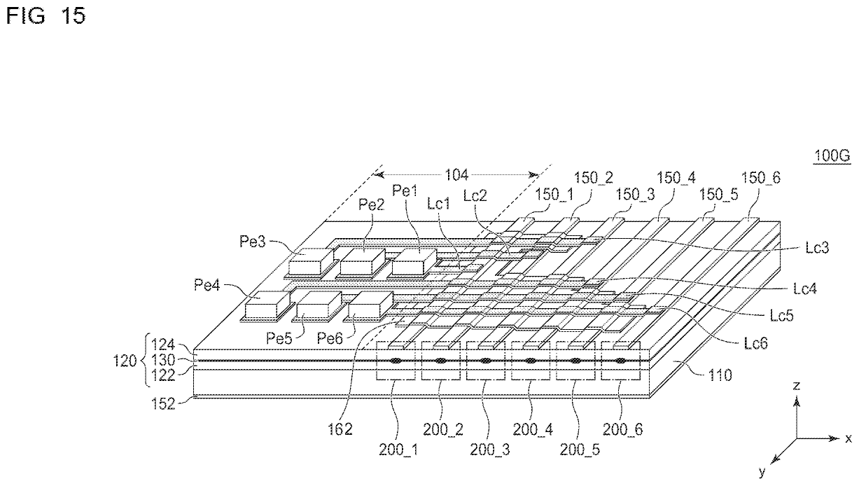

FIG. 15 is a perspective view of a semiconductor laser element 100G according to an eighth embodiment. In the semiconductor laser element 100G, six electrode pads Pe1 to Pe6 are arranged in three rows. According to this configuration, the strength when junction-down mounting is performed can be further increased. In addition, the configuration is effective in a case where the resonator length, that is, the length of the chip in the y direction is short.

Although the interlayer insulating film 162 is independently formed for each of the connection wirings Lc in the above-described first embodiment to seventh embodiment, the interlayer insulating film 162 may be continuously formed as illustrated in FIG. 15.

Some examples of the formation range of the interlayer insulating film 162 will be described.

### Ninth Embodiment

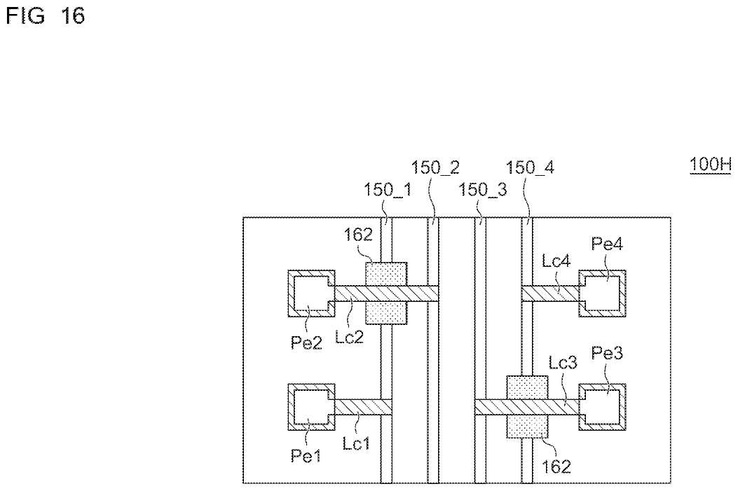

FIG. 16 is a plan view of a semiconductor laser element 100H according to a ninth embodiment. The interlayer insulating film 162 is provided only at a position where the connection wiring Lc intersects with the power supply electrode 150 and insulation is required. In this configuration, the interlayer insulating film 162 may be formed of either SiO₂ or polyimide.

### Tenth Embodiment

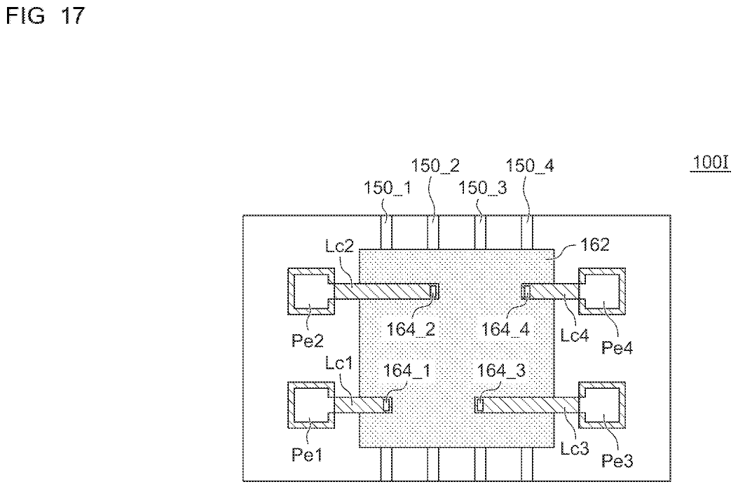

FIG. 17 is a plan view of a semiconductor laser element 100I according to a tenth embodiment. The interlayer insulating film 162 is formed to be wide over the range where the plurality of connection wirings Lc are formed, and is formed on a region that does not cover the electrode pad. Here, the interlayer insulating film 162 is not formed in the vicinity of the resonator end face, and is likely to be cleaved and pelletized. In this configuration, the interlayer insulating film 162 covers substantially the entire laser region 102, and can prevent an electrical short between the power supply electrodes 150_i. The configuration is also effective for preventing electrical short due to adhesion of conductive foreign matter in a manufacturing step or an assembly step of a narrow pitch multi-beam laser. In addition, the effect of heat dissipation by the interlayer insulating film itself and the effect of heat dissipation on the connection wiring due to the large area of the connection wiring to be provided on top of the interlayer insulating film can be obtained. The interlayer insulating film 162 has an opening 164_i at a position where the connection wiring Lc_i (i=1, 2, 3, and 4) and the power supply electrode 150_i are to be connected. In this configuration, the interlayer insulating film 162 may be formed of either SiO₂ or polyimide.

### Eleventh Embodiment

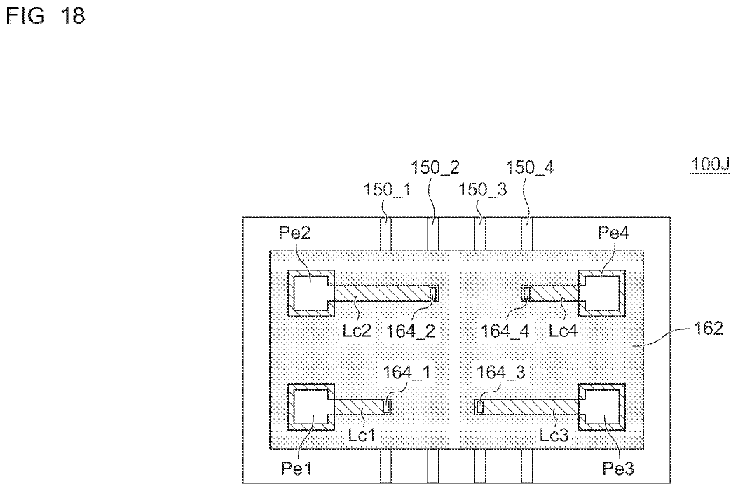

FIG. 18 is a plan view of a semiconductor laser element 100J according to an eleventh embodiment. The interlayer insulating film 162 is formed over a wide range including the electrode pads Pe1 to Pe4, and the connection wiring Lc and the electrode pad Pe are formed on the interlayer insulating film 162. Here, the interlayer insulating film 162 is not formed on the outer peripheral portion of the N-type semiconductor substrate 110, and is likely to be cleaved and pelletized. In this configuration, since there is no boundary of the interlayer insulating film 162 between the laser region and the pad region, a decrease in coverage of the connection wiring Lc at the boundary step can be prevented. In this configuration, the interlayer insulating film 162 may be formed of either SiO₂ or polyimide.

### Twelfth Embodiment

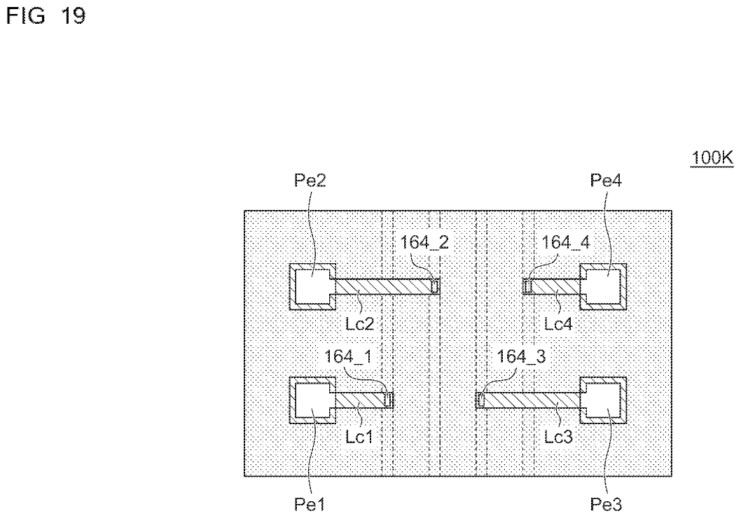

FIG. 19 is a plan view of a semiconductor laser element 100K according to a twelfth embodiment. The interlayer insulating film 162 is formed over the entire N-type semiconductor substrate 110. In this configuration, in a case where the interlayer insulating film 162 is formed of polyimide, cleavage and pelletization become difficult, and therefore a material that can be thinned, such as SiO₂, may be selected as the material of the interlayer insulating film 162.

### Thirteenth Embodiment

As described with reference to FIG. 4, by providing the thick film pad 170, it is possible to prevent the collision between the multilayered wiring structure 160 and the spacer 2, but on the other hand, the gap between the surface of the semiconductor laser element 100 and the surface of the spacer 2 becomes wider. Therefore, when one end face of the semiconductor laser element 100 is being coated, the material of the coating may wrap around and adhere to the opposite end face through this gap. Unintended coating material on the opposite end face may cause manufacturing variation or make it impossible to achieve the designed reflective properties. In the thirteenth embodiment, a technique for solving this problem will be described.

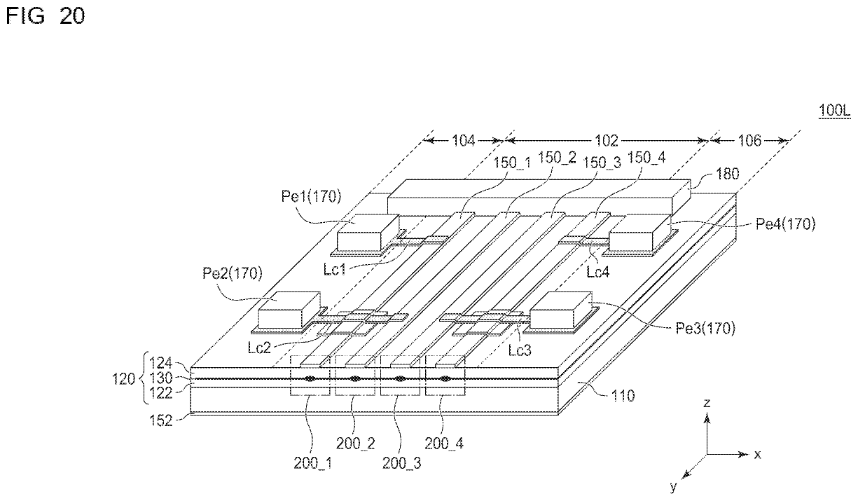

FIG. 20 is a perspective view of a semiconductor laser element 100L according to a thirteenth embodiment. The semiconductor laser element 100L includes a blocking wall 180 in addition to the thick film pad 170. The blocking wall 180 is formed across the plurality of laser resonators 200_1 to 200_4 in the x-direction and over at least the entire laser region 102. The blocking wall 180 has substantially the same height as the thick film pad 170. The blocking wall 180 may be made of a metal or an insulator. In a case where the blocking wall 180 is made of metal, an insulating layer is inserted between the blocking wall 180 and the power supply electrode 150. In addition, the blocking wall 180 may be made of the same material as or a different material from the thick film pad 170.

According to the semiconductor laser element 100L, since the blocking wall 180 and a spacer 2 come into contact with each other in the coating step, the material of the coating can be prevented from being wrapped around.

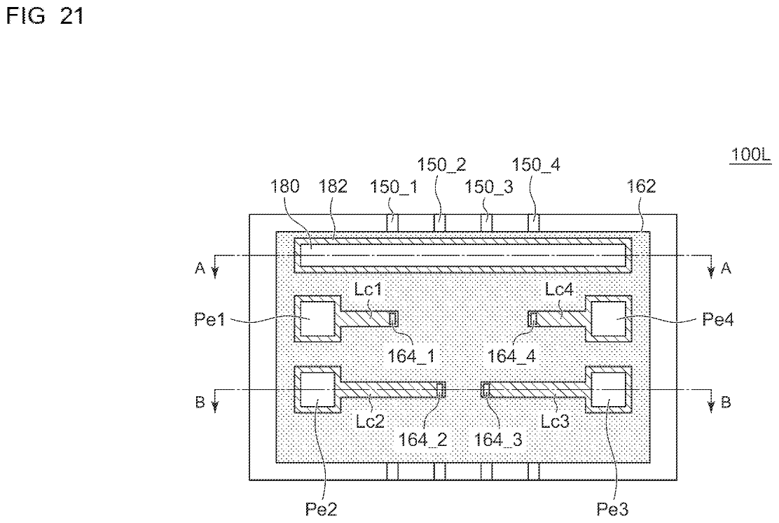

FIG. 21 is a plan view illustrating an example of the semiconductor laser element 100L in FIG. 20. The interlayer insulating film 162 is formed over a wide range excluding the outer periphery of the N-type semiconductor substrate 110, similarly to the semiconductor laser element 100J in FIG. 18.

In this embodiment, the blocking wall 180 is made of the same metal as the electrode pads Pe1 to Pe4. In the region where the blocking wall 180 is to be formed, the wiring layer 182 as a base is formed by the same material and the same process as the connection wiring Lc. The blocking wall 180 is formed on the wiring layer 182 by the same material and the same process as the electrode pad Pe.

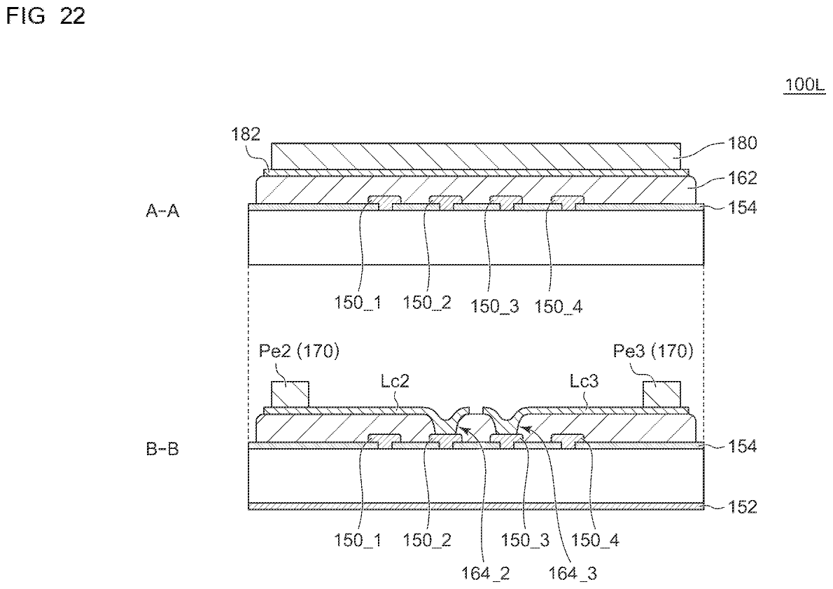

FIG. 22 is a cross-sectional view of the semiconductor laser element 100L in FIG. 21. The upper part of FIG. 22 is a cross-sectional view taken along line A-A of FIG. 21, and the lower part is a cross-sectional view taken along line B-B of FIG. 21.

### Fourteenth Embodiment

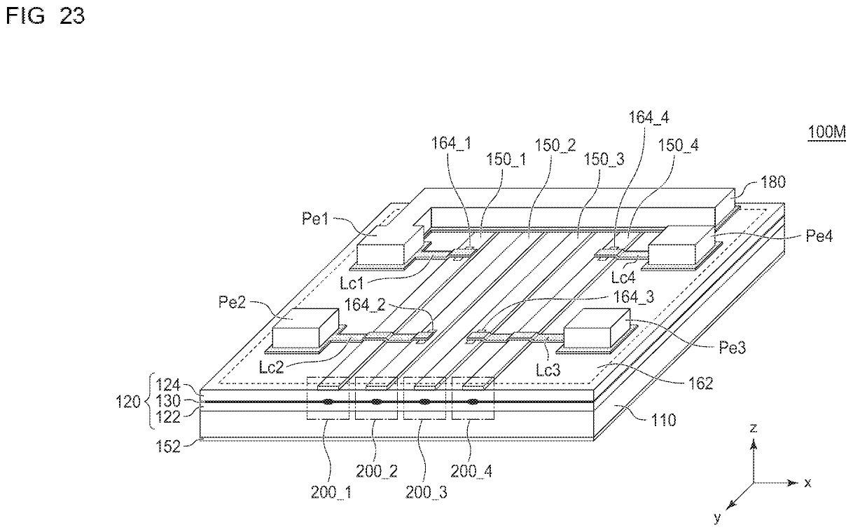

FIG. 23 is a perspective view of a semiconductor laser element 100M according to a fourteenth embodiment. The blocking wall 180 is continuously and integrally formed with one or some (in this example, the electrode pad Pe1) of the plurality of electrode pads Pe1 to Pe4.

### Method for Manufacturing

Next, a method for manufacturing the semiconductor laser element 100 in which the electrode pad Pe also serves as the thick film pad 170 will be described. This method for manufacturing includes a plating step of forming the thick film pad 170 by plating.

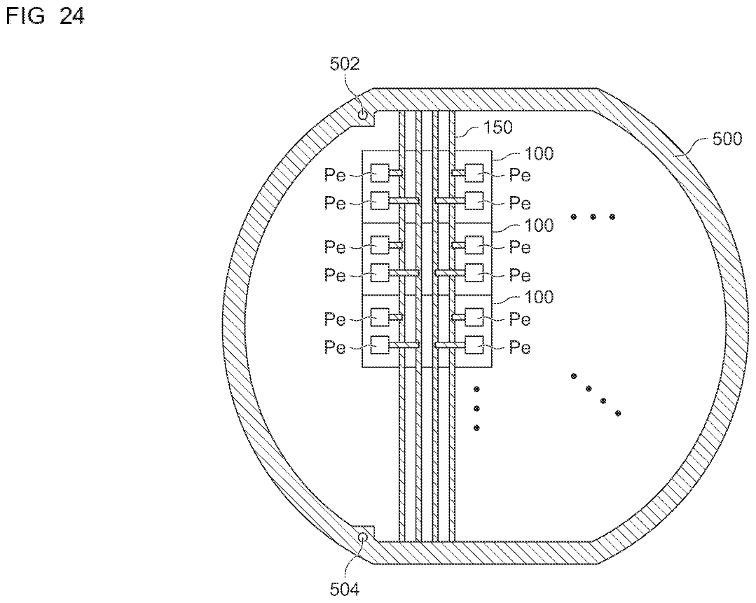

FIG. 24 is a diagram for describing a method for manufacturing the semiconductor laser element 100. The power supply electrode 150 of the semiconductor laser element 100 is continuous with the power supply electrode 150 of the adjacent semiconductor laser element 100, and is electrically connected to plated power supply pins 502 and 504 provided on the outer periphery of the wafer 500.

In the plating step, a photoresist is applied onto the wafer 500. The photoresist is opened in the plating film formation region. For example, in a case where a thick film pad is formed by plating, the photoresist is opened at the position where the thick film pad 170 is formed, that is, at the position of electrode pads Pe1 to Pe4. The wafer 500 is infiltrated with the plating solution, and power is supplied from the outside to the plated power supply pins 502 and 504. As a result, power is supplied to the electrode pad Pe via the power supply electrode 150 and the connection wiring Lc, and a thick film pad 170 can be formed on the electrode pad Pe by plating. That is, it is possible to omit a step of providing another power supply electrode wiring for supplying power to the thick film pad or removing unnecessary power supply electrode wiring after plating film formation, and it is possible to reduce the manufacturing cost. This method for manufacturing can be used in the same manner in a case where plating film formation is desired to increase the film thickness of the connection wiring parts. In this case, the photoresist is opened in the connection wiring part, and power is supplied to the connection wiring part that has been thinned by deposition or the like in advance via the power supply electrode 150, and plating is formed on the connection wiring part.

In the semiconductor laser element 100M in FIG. 23, power is supplied to the electrode pad Pe and the wiring layer 182 that is the base of the blocking wall 180 by this plating method, and therefore the blocking wall 180 can be formed simultaneously with the electrode pad Pe.

While the preferred embodiments of the present disclosure have been described using specific terms, such description is for illustrative purposes only, and it is to be understood that changes and variations may be made without departing from the spirit or scope of the appended claims.

What is claimed is:

1. A multibeam semiconductor laser element comprising:
a plurality of three or more laser resonators that is integrated adjacent to each other in a first direction in a laser region of a single semiconductor substrate, each laser resonator having an independent power supply electrode, a second direction being a longitudinal direction, and end faces being coated;
a plurality of electrode pads that is corresponding to the plurality of laser resonators and formed in a pad region adjacent to the laser region in the first direction; and
a plurality of wirings for connection that is corresponding to the plurality of laser resonators, each of the wirings for connection extending in the first direction, and electrically connecting the electrode pad corresponded to the power supply electrode of the laser resonator corresponded, the wirings for connection having a multilayered wiring structure at a position intersecting the laser resonator; and
a thick film pad that is formed in the pad region and has a height higher than a height of the multilayered wiring structure of the wirings for connection.

2. The multibeam semiconductor laser element according to claim 1, wherein the thick film pad is formed of the same material as the electrode pad.

3. The multibeam semiconductor laser element according to claim 1, wherein a height of the electrode pad is higher than a height of the multilayered wiring structure of the wirings for connection, and the electrode pad is the thick film pad.

4. The multibeam semiconductor laser element according to claim 1, wherein the thick film pad is provided separately from the plurality of electrode pads.

5. The multibeam semiconductor laser element according to claim 1, wherein the power supply electrode is a stripe-shaped electrode, an interlayer insulating film is formed on the stripe-shaped electrode, and the plurality of wirings for connection is formed on the interlayer insulating film.

6. The multibeam semiconductor laser element according to claim 5, wherein the interlayer insulating film is polyimide.

7. The multibeam semiconductor laser element according to claim 5, wherein the thick film pad is formed of the same material as the interlayer insulating film.

8. The multibeam semiconductor laser element according to claim 1, further comprising a blocking wall formed on the plurality of laser resonators, extending in the first direction, and having substantially the same height as the thick film pad.

9. The multibeam semiconductor laser element according to claim 8, wherein the power supply electrode is a stripe-shaped electrode, an interlayer insulating film is formed on the stripe-shaped electrode, and the blocking wall is formed of the same material as the interlayer insulating film.

10. The multibeam semiconductor laser element according to claim 1, wherein a plurality of the thick film pads are provided, and heights of the plurality of thick film pads are substantially equal.

11. The multibeam semiconductor laser element according to claim 1, wherein an interval between the plurality of laser resonators is 100 μm or less.

12. A semiconductor laser device comprising:
the multibeam semiconductor laser element according to claim 1; and
a support substrate;
the multibeam semiconductor laser element being mounted on the support substrate in a junction-up manner.

13. A semiconductor laser device comprising:
the multibeam semiconductor laser element according to claim 1; and
a support substrate;
the multibeam semiconductor laser element being mounted on the support substrate in a junction-down manner.

14. The semiconductor laser device according to claim 13, wherein
the support substrate includes a plurality of substrate-side electrode pads corresponding to the plurality of laser resonators, and each substrate-side electrode pad is formed in such a manner of overlapping the wirings for connection and the electrode pad of the corresponding laser resonator, and
the wirings for connection and the electrode pad of each laser resonator are bonded to a corresponding substrate-side electrode pad by solder.

15. A method for manufacturing the multibeam semiconductor laser element according to claim 1, the method comprising:
a plating step of forming the wirings for connection and the thick film pad by plating,
the power supply electrode being a stripe-shaped electrode, and
the power supply in the plating step being performed through the stripe-shaped electrode.
